(19) United States
(12) Patent Application Publication
(10) Pub. No.: US 2014/0110715 A1
(43) Pub. Date: Apr. 24, 2014

(54) Thin Film Transistor Array Panel and Manufacturing Method Thereof

(71) Applicant: INDUSTRIAL TECHNOLOGY RESEARCH INSTITUTE, Hsinchu (TW)

(72) Inventors: Chih-Ming LAI, Changhua County (TW); Yung-Hui YEH, Hsinchu City (TW)

(73) Assignee: Industrial Technology Research Institute, Hsinchu (TW)

(21) Appl. No.: 13/853,900

(22) Filed: Mar. 29, 2013

(30) Foreign Application Priority Data
Oct. 24, 2012 (TW) 101139219

(51) Int. Cl. H01L 27/15; H01L 33/00

(52) U.S. Cl. CPC H01L 27/156; H01L 33/005
USPC 257/59; 257/72; 438/34

(57) ABSTRACT

A thin film transistor (TFT) array display panel and a manufacturing method thereof are provided. The TFT array panel may comprise a substrate, a pixel array and an absorption layer. The substrate has an upper surface. The pixel array may be formed on the upper surface of the substrate and comprises several data lines, several scan lines and several active elements. The data lines and the scan lines define several pixel areas. Each active element is formed in the corresponding pixel area, and may comprise a channel layer. The absorption layer and the channel layer may be formed on the same layer structure.

This application claims the benefit of Taiwan application Serial No. 101139219, filed Oct. 24, 2012, the disclosure of which is incorporated by reference herein in its entirety.

### TECHNICAL FIELD

The disclosure relates in general to a thin film transistor (TFT) array display panel and a manufacturing method thereof, relates to a TFT array panel with active elements and a manufacturing method thereof.

### BACKGROUND

The oxidation film used for forming thin film transistor is normally formed by using the plasma process (such as PECVD). However, the plasma atmosphere contains free ions, which may easily enter the oxidation film and cause the gate voltage of the thin film transistor to be offset towards negative values, hence deteriorating the stability of the thin film transistor.

### SUMMARY

According to one embodiment, a thin film transistor (TFT) array display panel is provided. The TFT array panel comprises a substrate, a pixel array and an absorption layer. The substrate has an upper surface. The pixel array is formed on the upper surface of the substrate and comprises several data lines, several scan lines and several active elements. The scan lines and the data lines define several pixel areas. Each active element is formed in the corresponding pixel area, and comprises a channel layer. The absorption layer and the channel layer are made of the same material and formed on the same layer structure.

According to another embodiment, a manufacturing method of TFT display panel is provided. The manufacturing method comprises the following steps. A substrate having an upper surface is provided. A pixel array is formed on the upper surface of the substrate, wherein the method further comprises the following steps of forming several data lines on the substrate; forming several scan lines on the substrate, wherein the scan lines and the data lines define several pixel areas; and concurrently forming a channel layer and an absorption layer of an active element, wherein the absorption layer and the channel layer are made of the same material and formed on the same layer structure.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1A shows a top view of a TFT array panel according to an embodiment of the disclosure;

FIG. 1B shows an enlargement diagram of a portion 1B′ of FIG. 1A;

FIG. 1C shows a cross-sectional view along direction 1C-1C′ of FIG. 1B;

FIG. 2A shows a top view of an active element of a TFT array panel according to another embodiment of the disclosure;

FIG. 2B shows a cross-sectional view along direction 2B-2B′ of FIG. 2A;

FIG. 3 shows a cross-sectional view of an active element of a TFT array panel according to another embodiment of the disclosure;

FIG. 4A shows a partial top view of a pixel array of a TFT array panel according to another embodiment of the disclosure;

FIG. 4B shows a cross-sectional view along direction 4B-4B′ of FIG. 4A;

FIG. 5A shows a according to another embodiment of the disclosure partial top view of a pixel array of a TFT array panel.

FIG. 5B shows a cross-sectional view of along direction 5B-5B′ FIG. 5A;

FIG. 6 shows a partial top view of a pixel array of a TFT array panel according to another embodiment of the disclosure;

FIG. 7A shows a partial top view of a pixel array of a TFT array panel according to another embodiment of the disclosure;

FIG. 7B shows a cross-sectional view of along direction 7B-7B′ of FIG. 7A;

FIG. 8A shows a partial top view of a pixel array of a TFT array panel according to another embodiment of the disclosure;

FIG. 8B shows a cross-sectional view along direction 8B-8B′ of FIG. 8A;

FIG. 9 shows a partial top view of a pixel array of a TFT array panel according to another embodiment of the disclosure;

FIG. 10A shows a partial top view of a pixel array of a TFT array panel according to another embodiment of the disclosure;

FIG. 10B shows a cross-sectional view along direction 10B-10B′ of FIG. 10A;

FIG. 11A shows a partial top view of a pixel array of a TFT array panel according to another embodiment of the disclosure;

FIG. 11B shows a cross-sectional view along direction 11B-11B′ of FIG. 11A;

FIG. 12 shows a partial top view of a pixel array of a TFT array panel according to another embodiment of the disclosure;

FIGS. 13A˜13E are processes of a manufacturing method of a TFT array panel of FIG. 1B.

FIGS. 14A˜14E are processes of a manufacturing method of a TFT array panel of FIG. 4A.

FIGS. 15A˜15E are processes of a manufacturing method of a TFT array panel of FIG. 7A;

FIGS. 16A˜16E are processes of a manufacturing method of a TFT array panel of FIG. 10A.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

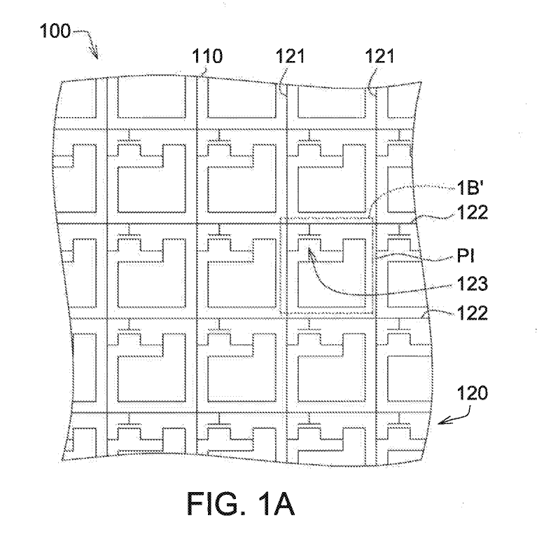

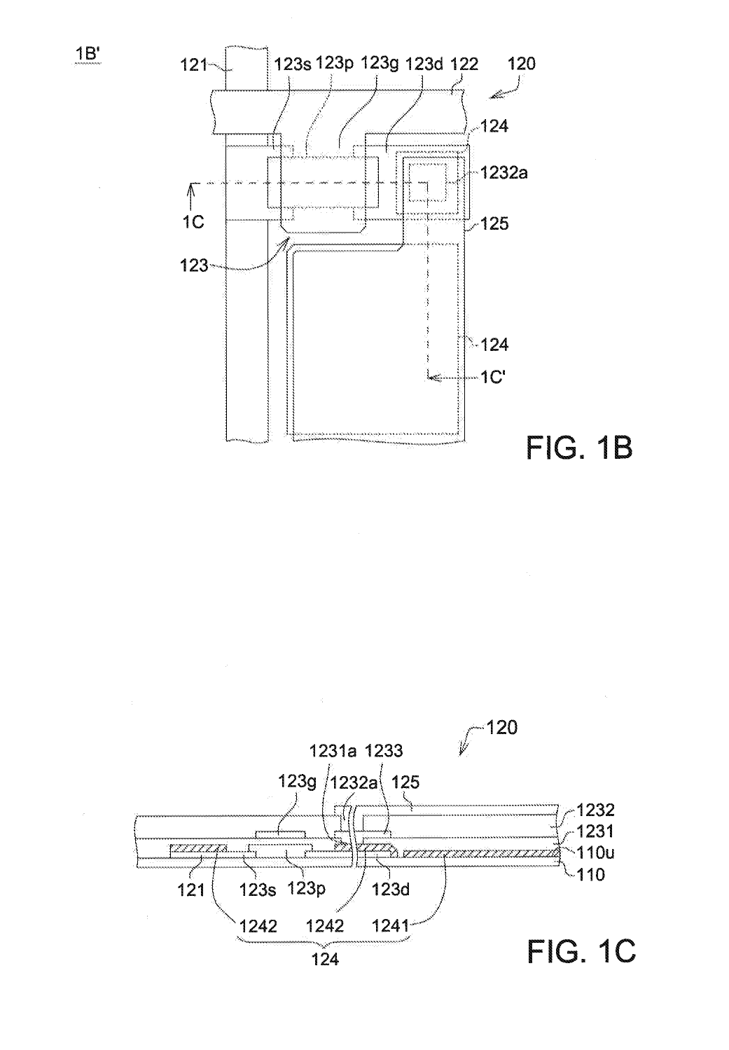

Referring to FIG. 1A, a top view of a TFT array panel according to an embodiment of the disclosure is shown. The TFT array panel 100 comprises a substrate 110 and a pixel array 120.

The substrate 110 is realized by such as a plastic substrate or a glass substrate. The pixel array 120 comprises several data lines 121, several scan lines 122, several active elements 123 and an absorption layer 124 (FIG. 1B). The scan lines 122 and the data lines 121 define several pixel areas Pl. Each active element 123 is formed in the corresponding pixel area Pl.

Referring to FIG. 1B, an enlargement diagram of a portion 1B′ of FIG. 1A is shown. The active elements 123 of the present embodiment are a staggered top gate thin film transistor. Each active element 123 comprises a source 123s, a drain 123d, a gate 123g and a channel layer 123p, wherein the region of the channel layer 123p corresponds to the gate 123g, and connects the source 123s and the drain 123d. The source 123s and the drain 123d are formed by such as metal.

Despite not being illustrated in the diagram, the pixel array 120 further comprises at least one common line which can be concurrently formed with the scan lines 122.

Referring to FIG. 1C, a cross-sectional view along direction 1C-1C′of FIG. 1B is shown. The source 123s, the drain 123d and the channel layer 123p are formed on the upper surface 110u of the substrate 110.

Each active element 123 further comprises a first insulating layer 1231, a second insulating layer 1232 and an electrical connection portion 1233, wherein the first insulating layer 1231 covers the channel layer 123p, the source 123s, the drain 123d and the absorption layer 124, and the gate 123g is formed on the upper surface of the first insulating layer 1231. The first insulating layer 1231 has a first aperture 1231a exposing the absorption layer 124. The electrical connection portion 1233 contacts the absorption layer 124 via the first aperture 1231a. The second insulating layer 1232 covers the gate 123g and the electrical connection portion 1233, and has a second aperture 1232a exposing the electrical connection portion 1233. In addition, the first insulating layer 1231 and the second insulating layer 1232 are formed by such as silicon nitride (SiNx), silicon dioxide (SiO₂), alumina (Al₂O₃).

The absorption layer 124 can absorb the residual of ions left on the active elements 123 during the process of forming the active elements 123 to avoid these ions or molecules, such as hydrogen ions (—H), hydroxide ions (—OH) and/or water vapor (H₂O), affecting the electrical quality of the active elements 123. Although different processes will result in different varieties of ions, the absorption layer 124 still can absorb these ions as long as the material of the absorption layer 124 is adjusted.

In terms of the electrical properties of the absorption layer 124, when both the upper layer and the lower layer of the absorption layer are realized by a conductive layer, the ratio of the voltage and the current passing through the absorption layer 124 is close to a constant. This implies that the absorption layer 124 whose resistance is not sensitive to the variation in voltage and current can be used as a conductive medium between two conductive layers (such as between the drain 123d and the electrical connection portion 1233). Since the absorption layer 124 has good electrical properties, there is no need to perform additional doping process and/or heat treatment on the absorption layer 124. However, practical applications are not limited thereto.

The absorption layer 124 and the channel layer 123p may be concurrently formed by the same material in the same process as if they were formed on the same layer structure. The absorption layer 124 is realized by such as an oxide semiconductor film. In an example, the absorption layer 124 is formed by doping indium, aluminum, gallium, tin, hafnium (Hf) or a combination thereof to a zinc oxide (ZnO) film. The absorption layer 124 comprises a first portion 1241 and a second portion 1242, which are separated from each other, wherein the second portion 1242 covers a portion of the source 123s, a portion of the drain 123d and the data lines 121. The electrical connection portion 1233 electrically contacts the second portion 1242 of the absorption layer 124 via the first aperture 1231a. In the present embodiment, the second portion 1242 is separated from the channel layer 123p. However, the second portion 1242 may be directly connected to the channel layer 123p in another embodiment.

The pixel array 120 further comprises several pixel electrodes 125 formed on the second insulating layer 1232. Each pixel electrode 125 is electrically connected to the corresponding electrical connection portion 1233 via the corresponding second aperture 1232a of the second insulating layer 1232. In the present embodiment, the region of the pixel electrode 125 corresponds to the first portion 1241 of the absorption layer 124. The light enters the first portion 1241 of the absorption layer 124 through the pixel electrodes 125 and causes the first portion 1241 to generate electron hole pairs (EHP). Since the first portion 1241 and the drain 123d are electrically isolated from each other, the EHP will not cause the gate voltage to be offset towards negative value and the stability of the active elements will not deteriorate.

The pixel electrodes 125 are realized by such as transparent electrode or metal layer, wherein the transparent electrode formed by such as indium tin oxide and metal layer can be used as a reflective layer.

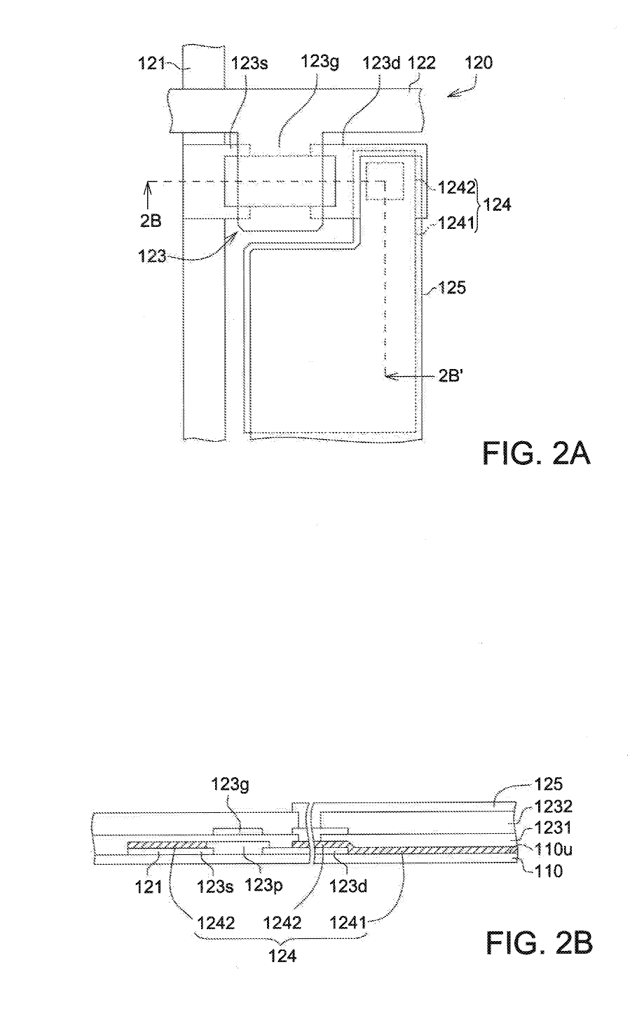

Referring to FIGS. 2A and 2B. FIG. 2A shows a top view of an active element of a TFT array panel according to another embodiment of the disclosure. FIG. 2B shows a cross-sectional view along direction 2B-2B′ of FIG. 2A. In the present embodiment, the first portion 1241 of the absorption layer 124 is directly connected to the second portion 1242 covering the drain 123d, wherein the first portion 1241 of the absorption layer 124 and the second portion 1242 are interconnected to form a continuous structure. In the present embodiment, the second portion 1242 is directly connected to the channel layer 123p. Under such design, the pixel electrode 125 can be a light-blocking metal layer which avoids the light radiating the absorption layer 124 and generating EHP. In another embodiment, the pixel electrode 125 can also be realized by a transparent electrode. In other examples, the second portion 1242 and the channel layer 123p are separated from each other. Under such design, the pixel electrode 125 can be realized by such as a metal layer or a transparent electrode.

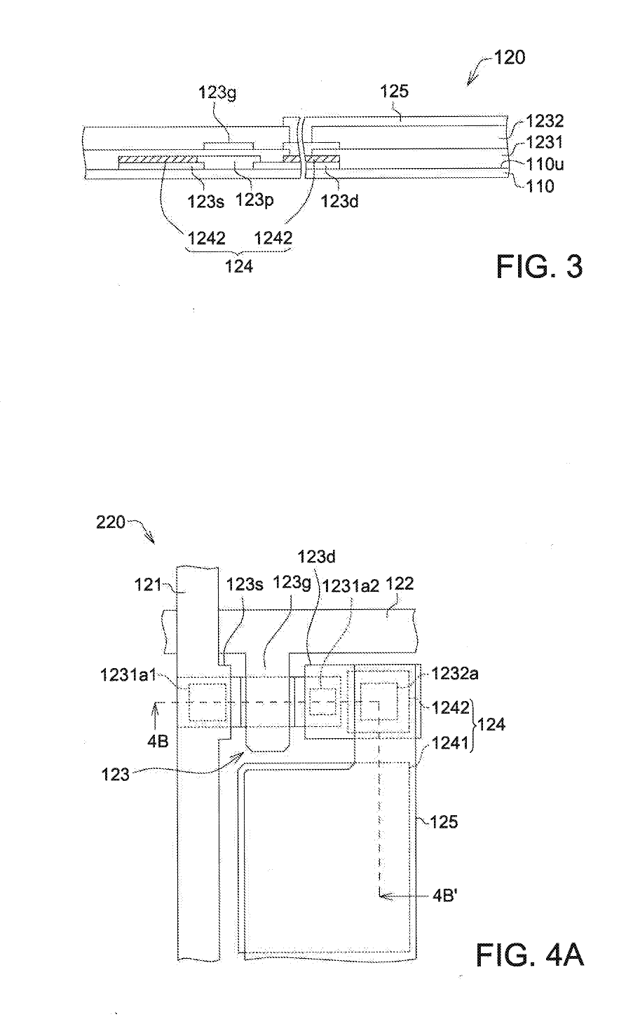

Referring to FIG. 3, a cross-sectional view of an active element of a TFT array panel according to another embodiment of the disclosure is shown. In comparison to the embodiment of FIG. 1A, the first portion 1241 of the absorption layer 124 is omitted, and the second portion 1242 is directly connected to the channel layer 123p in the present embodiment. In another embodiment, the second portion 1242 and the channel layer 123p may be separated from each other.

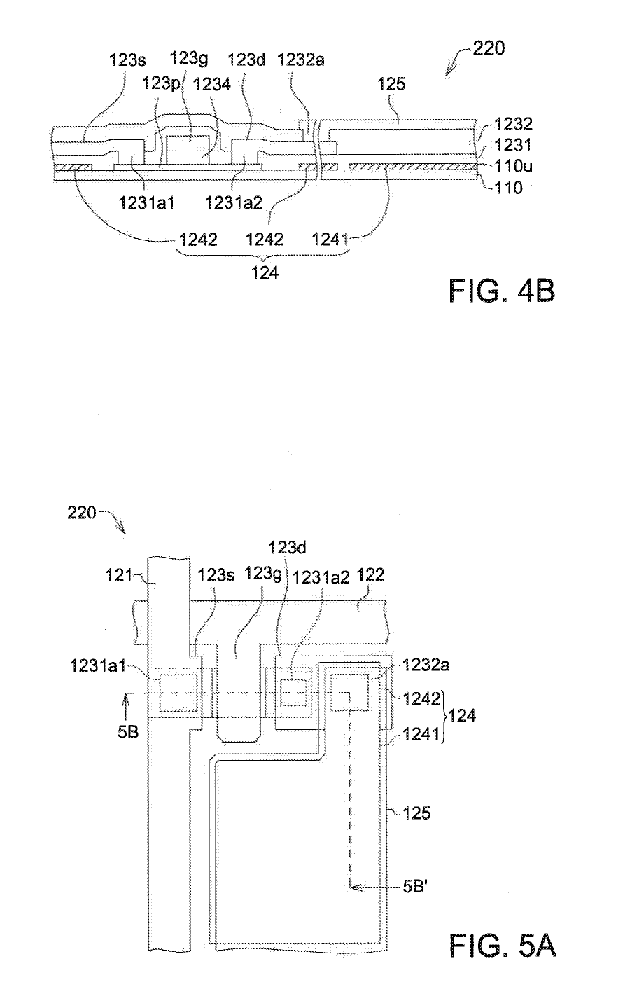

Referring to FIGS. 4A and 4B. FIG. 4A shows a partial top view of a pixel array of a TFT array panel according to another embodiment of the disclosure. FIG. 4B shows a cross-sectional view along direction 4B-4B′ of FIG. 4A. The pixel array 220 comprises several data lines 121 (only one line is illustrated), several scan lines 122 (only one line is illustrated), several active elements 123 (only one element is illustrated), an absorption layer 124 and several pixel electrodes 125. The scan lines 122 and the data lines 121 define several pixel areas. Each active element 123 is formed in the corresponding pixel area.

The active elements 123 of the present embodiment are a self-aligned top gate thin film transistor. Each active element 123 further comprises a gate 123g, a source 123s, a drain 123d, a channel layer 123p, a first insulating layer 1231, a second insulating layer 1232 and a gate dielectric layer 1234, wherein the channel layer 123p and the entire absorption layer 124 are formed on the upper surface 110u of the substrate 110, and the gate dielectric layer 1234 is formed on the channel layer 123p and located between the channel layer 123p and the gate 123g. The first insulating layer 1231 covers the channel layer 123p, the absorption layer 124, the gate dielectric layer 1234 and the gate 123g, and has two first apertures 1231a1 and 1231a2. The source 123s and the drain 123d are formed on the first insulating layer 1231, and are respectively connected to the channel layer 123p via the first apertures 1231a1 and 1231a2. The second insulating layer 1232 covers the first insulating layer 1231, and has a second aperture 1232a. The pixel electrode 125 is formed on the second insulating layer 1232, and is electrically connected to the drain 123d via the second aperture 1232a. In the present embodiment, the first portion 1241 of the absorption layer 124 and the second portion 1242 are separated from each other. However, the first portion 1241 and the second portion 1242 may also be connected to each other.

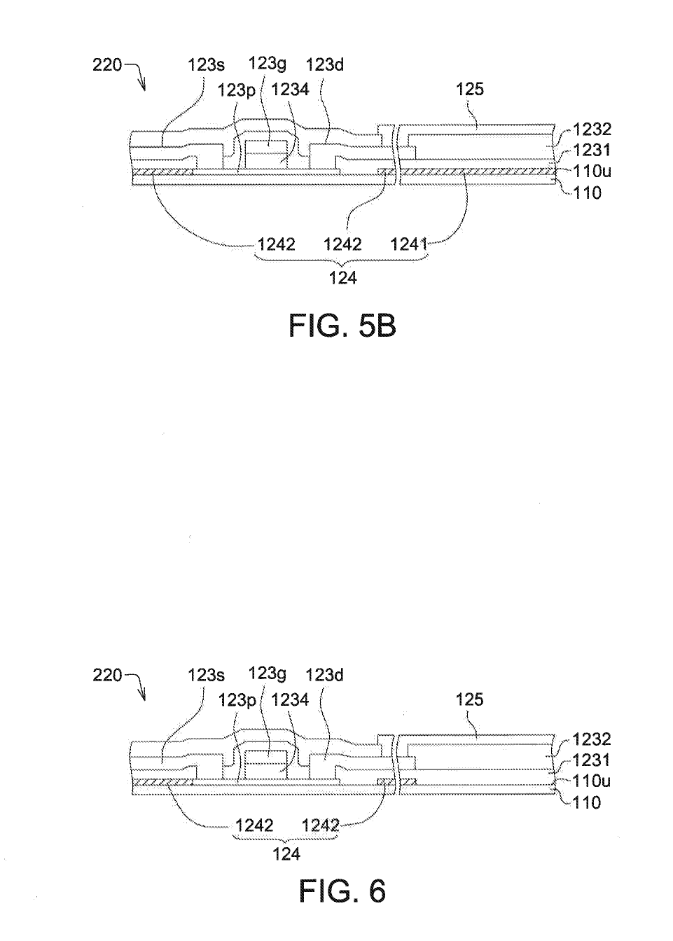

Referring to FIGS. 5A and 5B. FIG. 5A shows a according to another embodiment of the disclosure partial top view of a pixel array of a TFT array panel. FIG. 5B shows a cross-sectional view of along direction 5B-5B′ FIG. 5A. In the present embodiment, the absorption layer 124 opposite to the drain 123d (that is, the second portion 1242 at the right hand side of FIG. 5B) is connected to the first portion 1241. Although the light may enters the first portion 1241 of the absorption layer 124 through the pixel electrodes 125 to generate EHP, the first portion 1241 and the drain 123d being electrically isolated from each other will not cause negative effect to the active elements 123.

The second portion 1242 disposed underneath the source 123s is connected to the channel layer 123p, and is thus electrically connected to the active elements 123. The source 123s is a light blocking metal, the light will not radiate on the second portion 1242 through the source 123s to generate EHP.

Referring to FIG. 6, a partial top view of a pixel array of a TFT array panel according to another embodiment of the disclosure is shown. In comparison to the embodiment of FIG. 4B, the first portion 1241 of the absorption layer 124 is omitted, and the second portion 1242 of the absorption layer 124 is directly connected to the channel layer 123p in the present embodiment. In another embodiment, the absorption layer 124 and the channel layer 123p may be isolated from each other.

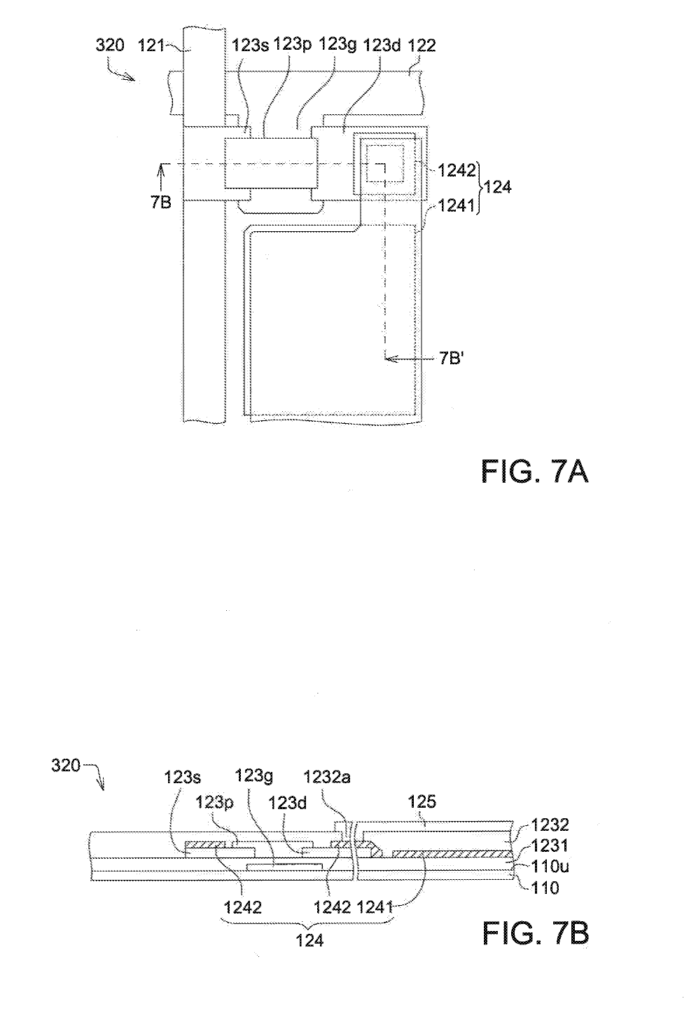

Referring to FIGS. 7A and 7B. FIG. 7A shows a partial top view of a pixel array of a TFT array panel according to another embodiment of the disclosure. FIG. 7B shows a cross-sectional view of along direction 7B-7B′ of FIG. 7A. The pixel array 320 comprises several data lines 121 (only one line is illustrated), several scan lines 122 (only one line is illustrated), several active elements 123 (only one element is illustrated), an absorption layer 124 and several pixel electrodes 125. The scan lines 122 and the data lines 121 define several pixel areas. Each active element 123 is formed in the corresponding pixel area.

The active elements 123 of the present embodiment are a co-planar bottom gate thin film transistor. Each active element 123 further comprises a gate 123g, a source 123s, a drain 123d, a channel layer 123p, a first insulating layer 1231, a second insulating layer 1232 and a gate dielectric layer 1234. The gate 123g is formed on the upper surface 110u of the substrate 110, and the first insulating layer 1231 covers the gate 123g. The source 123s, the drain 123d, the channel layer 123p, and the absorption layer 124 are formed on the first insulating layer 1231. The second portion 1242 of the absorption layer 124 covers a portion of the source 123s and a portion of the drain 123d. The second insulating layer 1232 covers the source 123s, the drain 123d, the channel layer 123p and the absorption layer 124, and has a second aperture 1232a. The pixel electrode 125 is formed on the second insulating layer 1232, and is connected to the second portion 1242 of the absorption layer 124 through the second aperture 1232a. In the present embodiment, the first portion 1241 of the absorption layer 124 and the second portion 1242 are separated from each other. In another embodiment, the first portion 1241 and the second portion 1242 can be connected to each other.

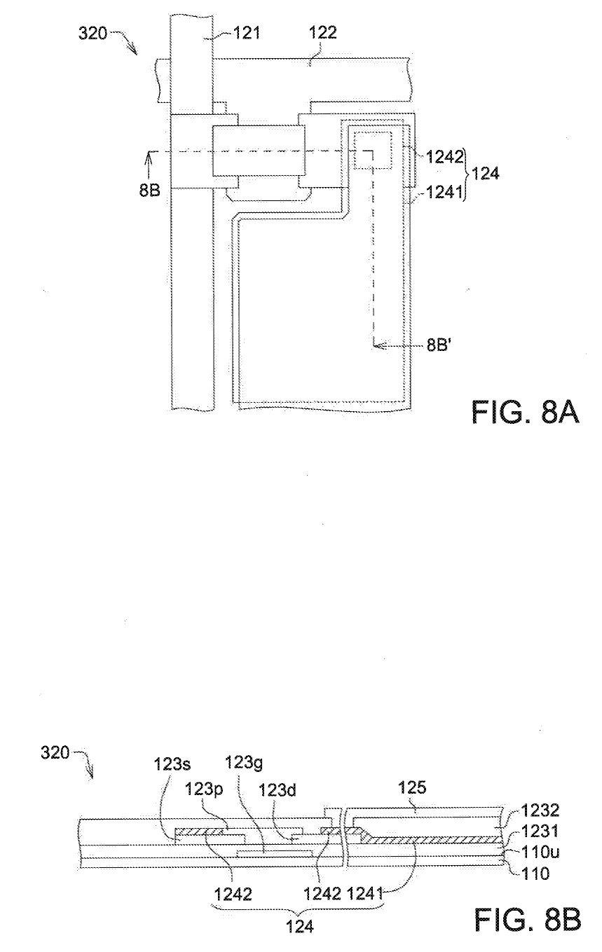

Referring to FIGS. 8A and 8B. FIG. 8A shows a partial top view of a pixel array of a TFT array panel according to another embodiment of the disclosure. FIG. 8B shows a cross-sectional view along direction 8B-8B′ of FIG. 8A. In the present embodiment, the absorption layer 124 covering on the drain 123d (that is, the second portion 1242 at the right hand side of FIG. 8B) is connected to the first portion 1241. The second portion 1242 disposed above the source 123s is connected to the channel layer 123p. In the present embodiment, the absorption layer 124 is electrically connected to the active element 123. Under such design, the pixel electrode 125 can be realized by such as a light blocking metal layer. In another embodiment, the pixel electrode 125 can also be realized by such as a transparent electrode.

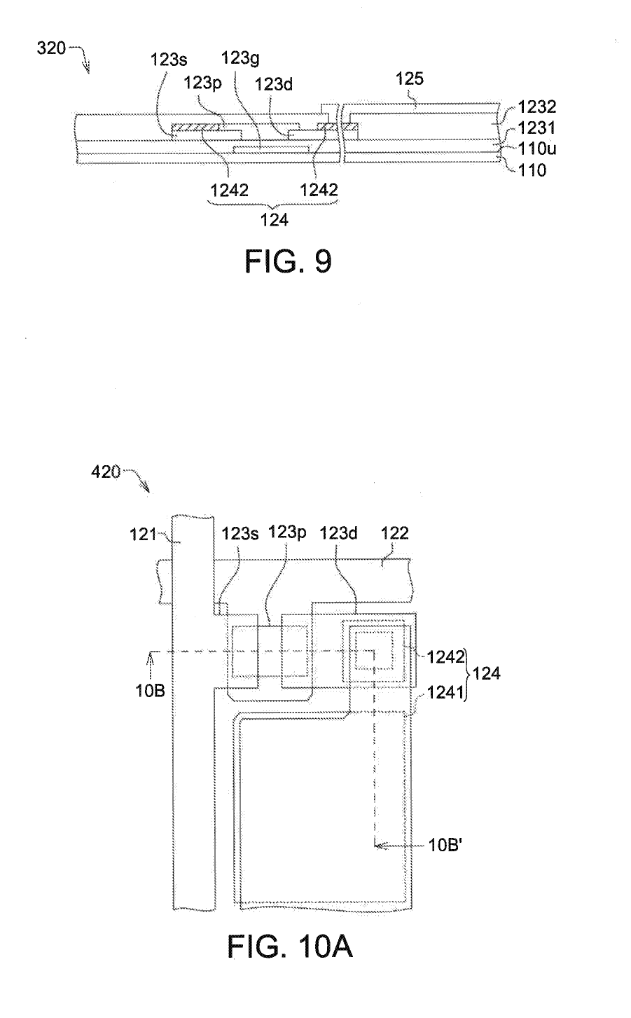

Referring to FIG. 9, a partial top view of a pixel array of a TFT array panel according to another embodiment of the disclosure is shown. In comparison to the embodiment of FIG. 7B, the first portion 1241 of the absorption layer 124 is omitted, and the second portion 1242 of the absorption layer 124 is directly connected to the channel layer 123p in the present embodiment. In another embodiment, the absorption layer 124 may be connected to the channel layer 123p.

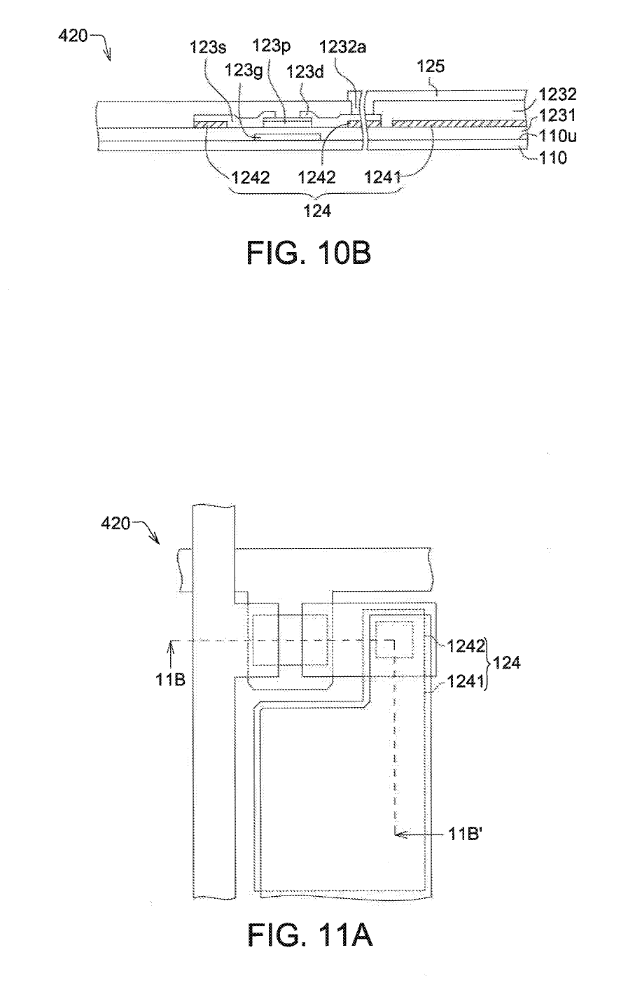

Referring to FIGS. 10A and 10B. FIG. 10A shows a partial top view of a pixel array of a TFT array panel according to another embodiment of the disclosure. FIG. 10B shows a cross-sectional view along direction 10B-10B′ of FIG. 10A. The pixel array 420 comprises several data lines 121 (only one line is illustrated), several scan lines 122 (only one line is illustrated), several active elements 123 (only one element is illustrated) and an absorption layer 124. The scan lines 122 and the data lines 121 define several pixel areas. Each active element 123 is formed in the corresponding pixel area.

In the present embodiment, the active elements 123 are a staggered bottom gate thin film transistor. Each active element 123 further comprises a gate 123g, a source 123s, a drain 123d, a channel layer 123p, a first insulating layer 1231 and a second insulating layer 1232. The gate 123g is formed on the upper surface 110u of the substrate 110, and the first insulating layer 1231 covers the gate 123g. The source 123s, the drain 123d, the channel layer 123p, and the absorption layer 124 are formed on the upper surface of the first insulating layer 1231. The second portion 1242 of the absorption layer 124 is covered by the source 123s and the drain 123d to avoid being radiated by the light and generating EHP. The second insulating layer 1232 covers the source 123s, the drain 123d, the channel layer 123p and the absorption layer 124, and has a second aperture 1232a. The pixel electrode 125 is formed on the second insulating layer 1232, and is connected to the second portion 1242 of the absorption layer 124 through the second aperture 1232a. In the present embodiment, the first portion 1241 of the absorption layer 124 and the second portion 1242 are separated from each other. In another embodiment, the first portion 1241 and the second portion 1242 may be connected to each other.

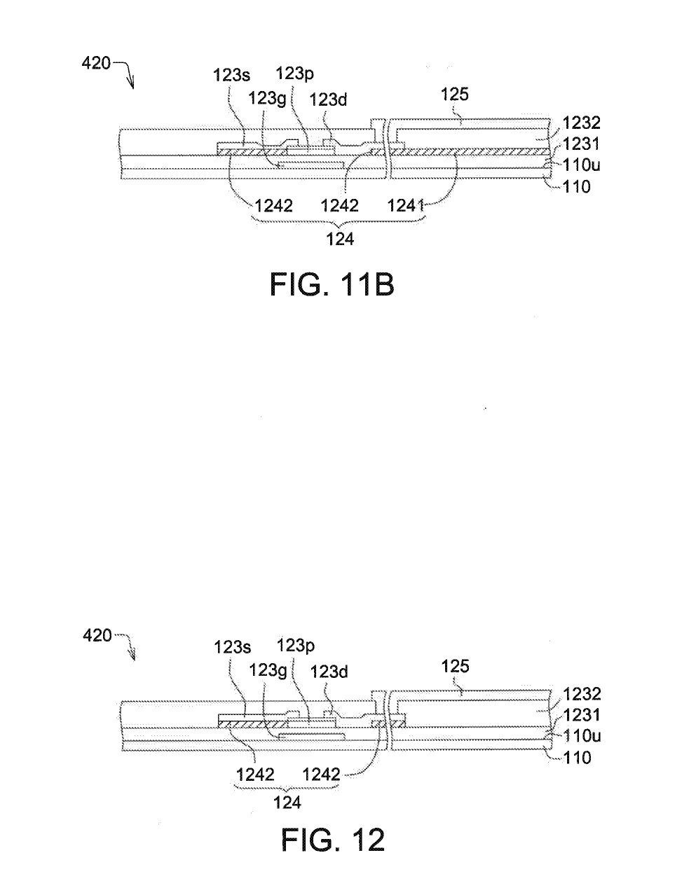

Referring to FIGS. 11A and 11B. FIG. 11A shows a partial top view of a pixel array of a TFT array panel according to another embodiment of the disclosure. FIG. 11B shows a cross-sectional view along direction 11B-11B′ of FIG. 11A. In the present embodiment, the absorption layer 124 covered by the drain 123d (that is, the second portion 1242 at the right hand side of FIG. 11B) is connected to the first portion 1241. The absorption layer 124 covered by the source 123s (that is, the second portion 1242 at the left hand side of FIG. 11B) is connected to the channel layer 123p. Although the absorption layer 124 of the present embodiment is electrically connected to the active elements 123, the absorption layer 124 is covered by the drain 123d and the source 123s to avoid the light entering the absorption layer 124 and generating EHP.

Referring to FIG. 12, a partial top view of a pixel array of a TFT array panel according to another embodiment of the disclosure is shown. In comparison to the embodiment of FIG. 10B, the first portion 1241 of the absorption layer 124 is omitted, and the second portion 1242 of the absorption layer 124 is directly connected to the channel layer 123p in the present embodiment. In another embodiment, the second portion 1242 and the channel layer 123p may be separated from each other.

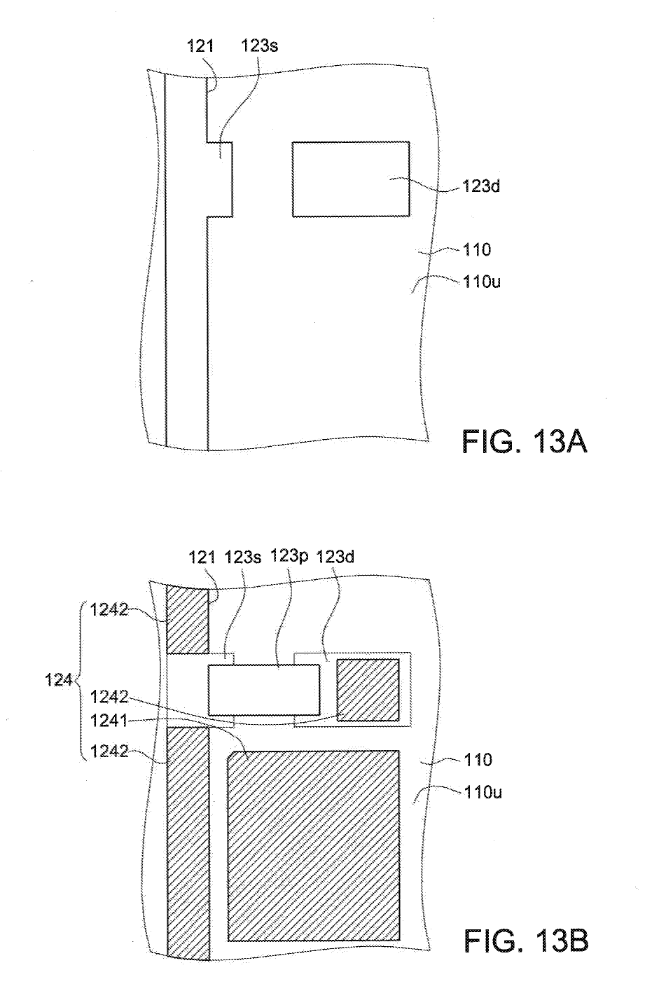

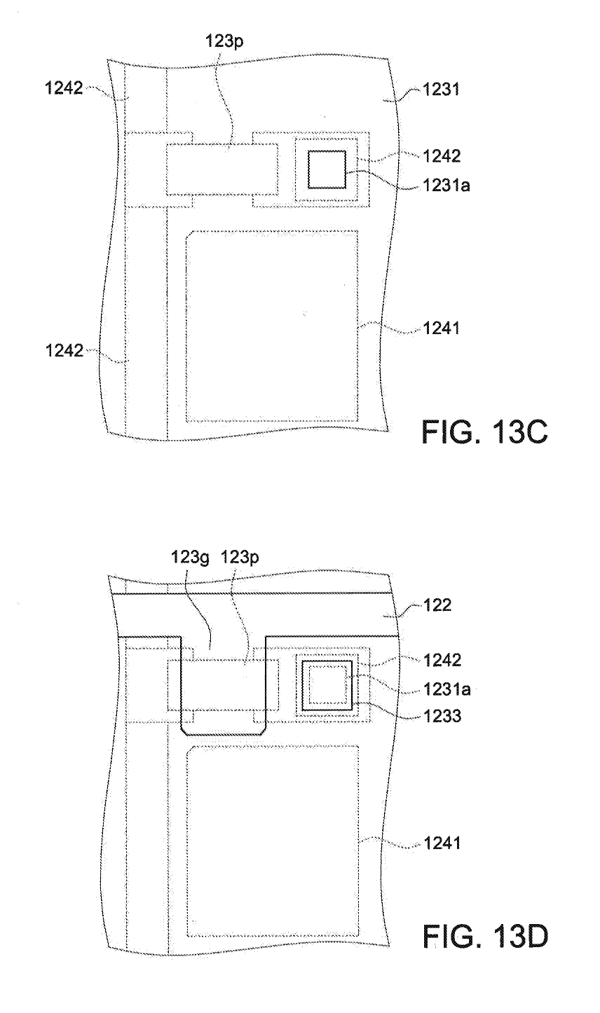

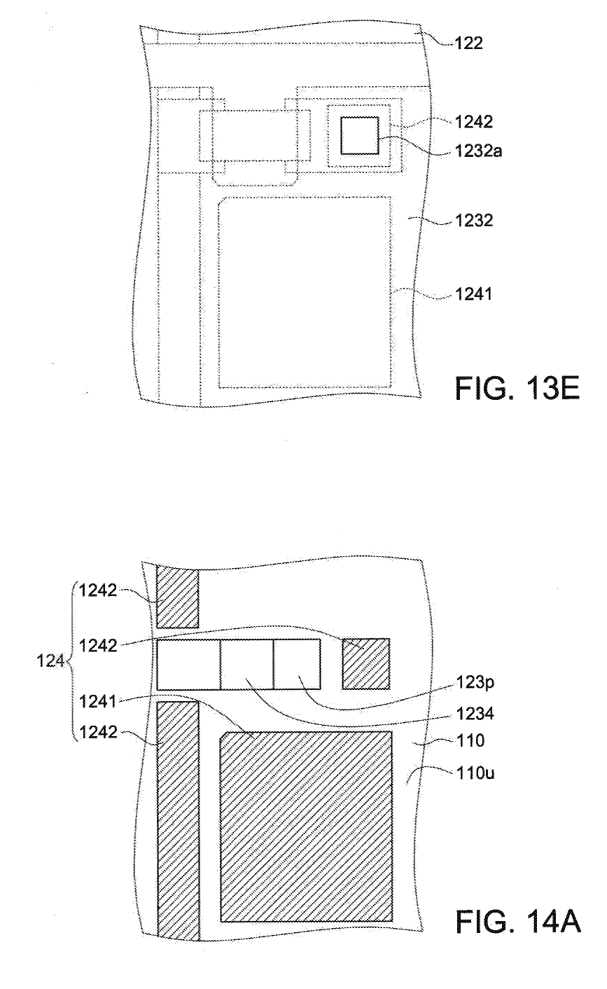

Referring to FIGS. 13A˜13E, processes of a manufacturing method of a TFT array panel of FIG. 1B are shown.

As indicated in FIG. 13A, a substrate 110 having an upper surface 110u is provided. The substrate 110 is realized by such as a glass substrate or a transparent high polymer substrate.

As indicated in FIG. 13A, several data lines 121, a source 123s and a drain 123d are formed on the substrate 110 by using such as the deposition, exposure or development process, wherein the deposition process is such as chemical vapor deposition, physical vapor deposition, sputtering or other suitable processing, and the chemical vapor deposition is such as plasma-enhanced chemical vapor deposition.

As indicated in FIG. 13B, the absorption layer 124 and the channel layer 123p are concurrently formed on the upper surface 110u of the substrate 110 by using such as the deposition, exposure or development process. The absorption layer 124 comprises a first portion 1241 and a second portion 1242, wherein the first portion 1241 covers the upper surface 110u of the substrate 110, and the second portion 1242 covers the data lines 121, a portion of the source 123s and a portion of the drain 123d. In another embodiment, the second portion 1242 only needs to cover at least one of the data lines 121, the source 123s and the drain 123d instead of concurrently covering the data lines 121, the source 123s and the drain 123d.

As indicated in FIG. 13C, a first insulating layer 1231 covering the source 123s, the drain 123d, the channel layer 123p and the absorption layer 124 (the covered structure is denoted by dotted lines) is formed by using such as the deposition or coating process. The coating process is such as printing, spin coating, spray coating and/or other suitable processing.

A first aperture 1231a exposing the second portion 1242 of the absorption layer 124 is formed in the first insulating layer 1231 by using such as the patterning process. The patterning process is such as photolithography and/or other suitable processing.

As indicated in FIG. 13D, the scan lines 122, the gate 123g and electrical connection portion 1233 are formed on the first insulating layer 1231 by using such as the deposition, exposure or development process, wherein the region of the gate 123g corresponds to the channel layer 123p, and the electrical connection portion 1233 contacts the second portion 1242 of the absorption layer 124 via the first aperture 1231a.

As indicated in FIG. 13E, the second insulating layer 1232 covering the gate 123g and the electrical connection portion 1233 (the covered structure is denoted by dotted lines) is formed by using such as the deposition or development process.

As indicated in FIG. 13E, a second aperture 1232a exposing the electrical connection portion 1233 is formed on the second insulating layer 1232 by using such as patterning technology.

The pixel electrode 125 of FIG. 1C is formed on the second insulating layer 1232 by using such as the deposition, exposure or development process, wherein the region of the pixel electrode 125 corresponds to the first portion 1241 of the absorption layer 124, and is electrically connected to the second portion 1242 of the absorption layer 124 via the corresponding second aperture 1232a.

The manufacturing method of the TFT array panel of FIGS. 2A and 3 is similar to that of FIG. 1B, and the similarities are not repeated here.

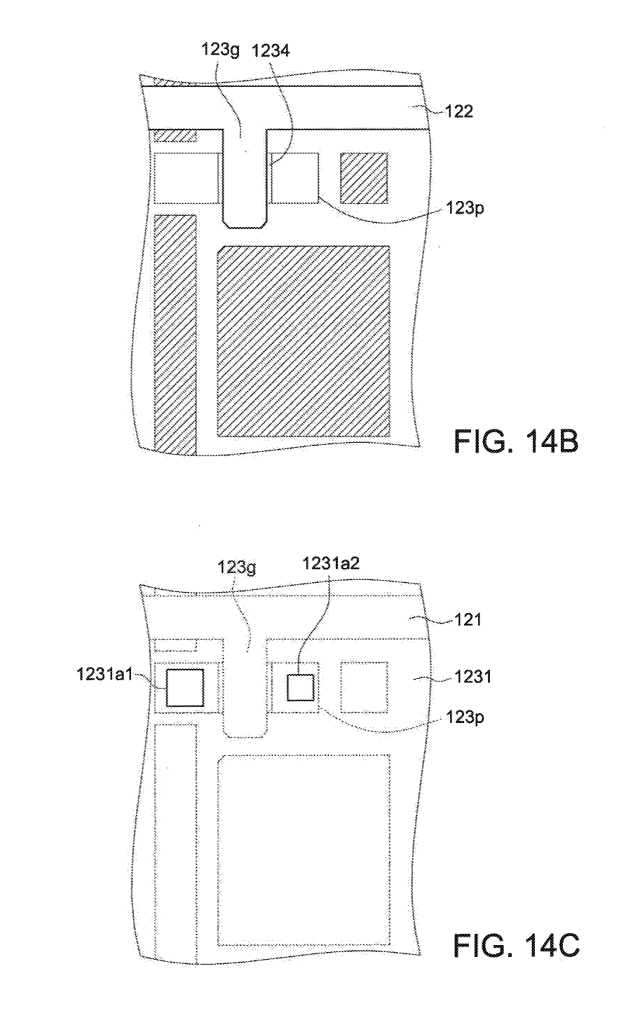

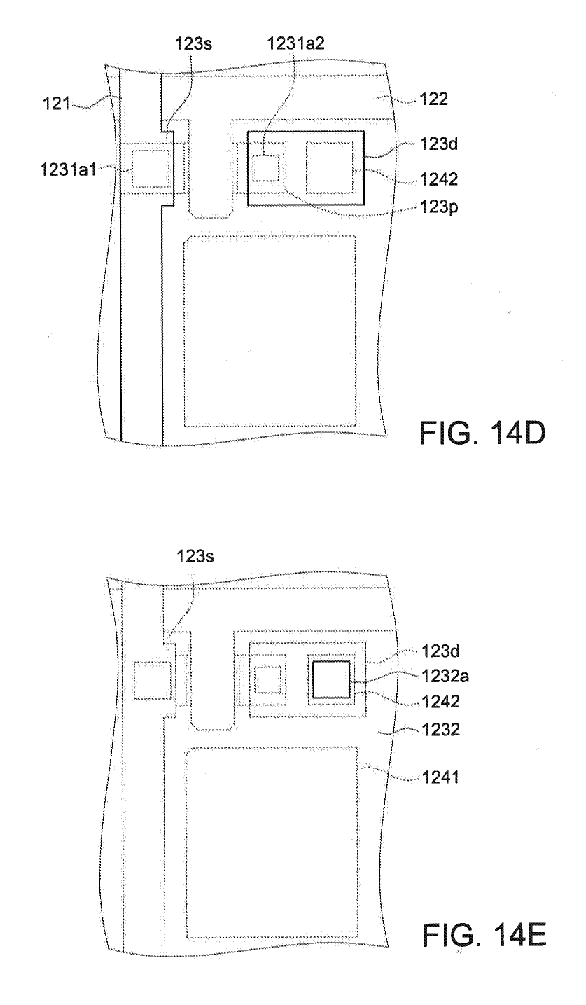

Referring to FIGS. 14A˜14E, processes of a manufacturing method of a TFT array panel of FIG. 4A are shown.

As indicated in FIG. 14A, a substrate 110 having an upper surface 110u is provided.

As indicated in FIG. 14A, a channel layer 123p and an absorption layer 124 are concurrently formed on the upper surface 110u of the substrate 110 by using such as the deposition, exposure or development process, wherein the absorption layer 124 comprises a first portion 1241 and a second portion 1242.

As indicated in FIG. 14A, a gate dielectric layer 1234 covering a portion of the channel layer 123p is formed by using such as the deposition, exposure or development process.

As indicated in FIG. 14B, several scan lines 122 and a gate 123g are formed on the upper surface 110u of the substrate 110 by using such as the deposition, exposure or development process, wherein the gate 123g is formed on the gate dielectric layer 1234, such that the gate dielectric layer 1234 is interposed between the gate 123g and the channel layer 123p.

As indicated in FIG. 14C, a first insulating layer 1231 covering the gate 123g, the channel layer 123p and the absorption layer 124 (the covered structure is denoted by dotted lines) is formed by using such as the deposition or development process.

As indicated in FIG. 14C, two first apertures 1231a1 and 1231a2 are formed on the first insulating layer 1231 by using such as the patterning technology, wherein the first apertures 1231a1 and 1231a2 expose the channel layer 123p at two sides of the gate 123g.

As indicated in FIG. 14D, several scan lines 122, a source 123s and a drain 123d are formed by using such as the deposition, exposure or development process, wherein the scan lines 122 overlap the second portion 1242 of the absorption layer 124, the source 123s is connected to the channel layer 123p via the first aperture 1231a1, and the drain 123d is connected to the channel layer 123p via the first aperture 1231a2.

As indicated in FIG. 14E, a second insulating layer 1232 covering scan lines 122, the source 123s and the drain 123d (the covered structure is denoted by dotted lines) is formed by using such as the deposition or development process.

As indicated in FIG. 14E, a second aperture 1232a exposing the drain 123d is formed on the second insulating layer 1232 by using such as the patterning technology.

Then, the pixel electrode 125 of FIG. 4A is formed on the second insulating layer 1232 by using such as the deposition, exposure or development process, wherein the region of the pixel electrode 125 corresponds to the first portion 1241 of the absorption layer 124, and is electrically connected to the second portion 1242 of the absorption layer 124 via the corresponding second aperture 1232a.

The manufacturing method of the TFT array panel of FIGS. 5A and 6 is similar to that of FIG. 4A, and the similarities are not repeated here.

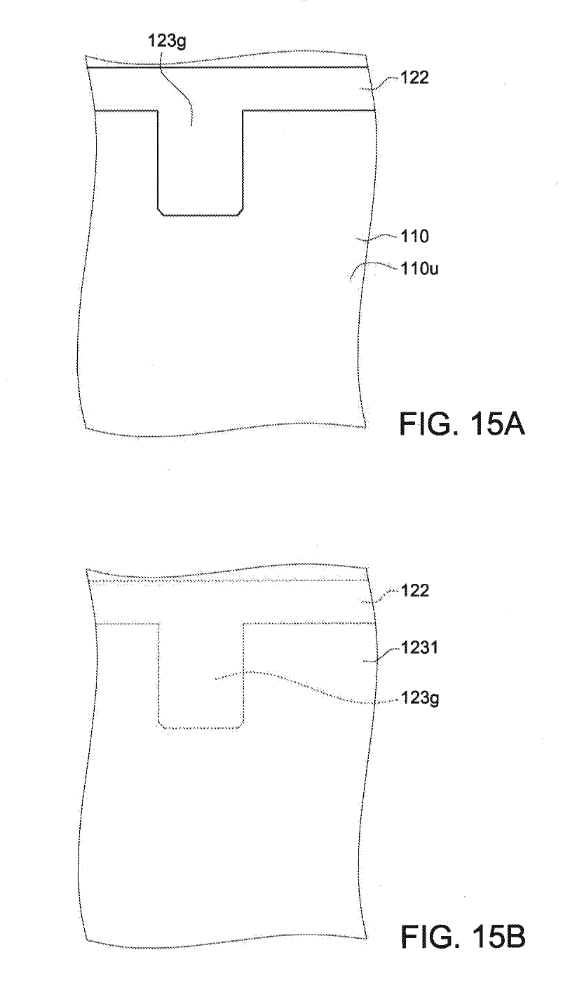

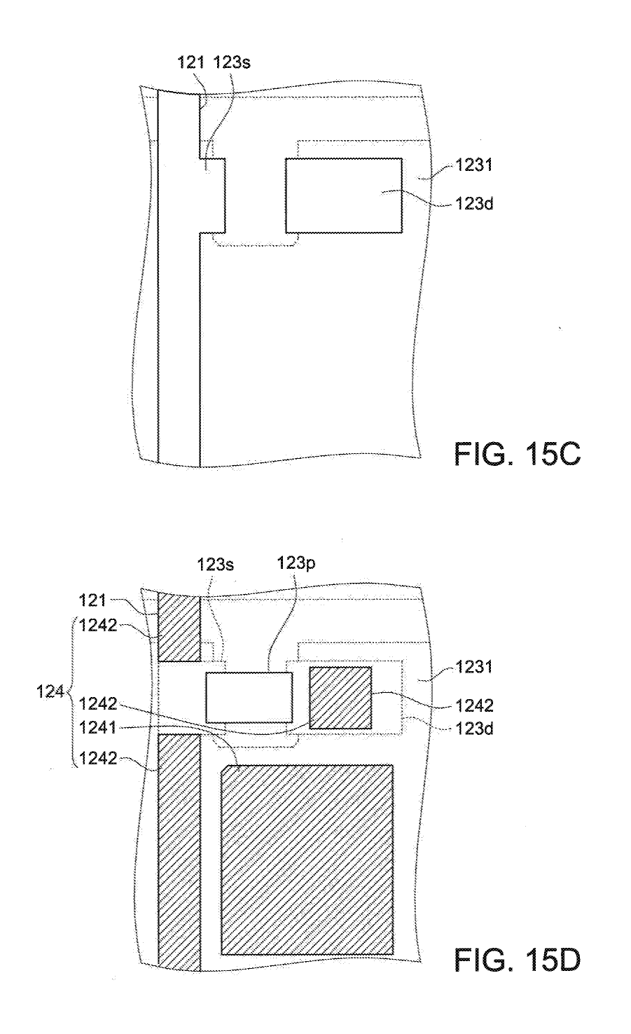

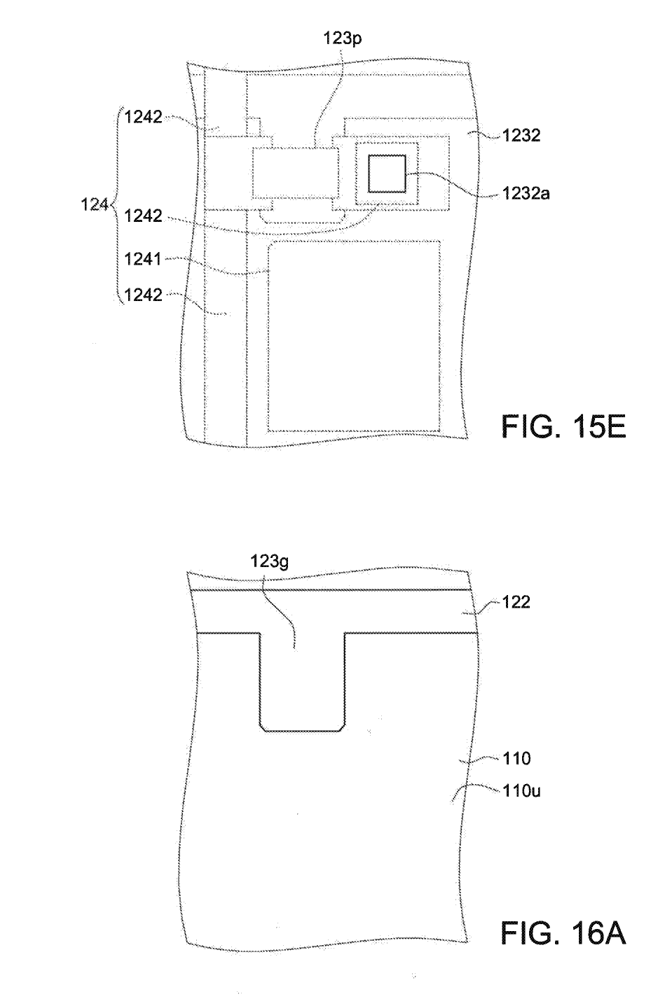

Referring to FIGS. 15A-15E, processes of a manufacturing method of a TFT array panel of FIG. 7A are shown.

As indicated in FIG. 15A, a substrate 110 having an upper surface 110u is provided.

As indicated in FIG. 15A, a gate 123g and several scan lines 122 are formed on the upper surface 110u of the substrate 110 by using such as the deposition, exposure or development process.

As indicated in FIG. 15B, a first insulating layer 1231 covering the gate 123g and the scan lines 122 (the covered structure is denoted by dotted lines) is formed by using such as the deposition or development process.

As indicated in FIG. 15C, several data lines 121, a source 123s and a drain 123d are formed on the first insulating layer 1231 by using such as the deposition, exposure or development process.

As indicated in FIG. 15D, a channel layer 123p and an absorption layer 124 are concurrently formed on the first insulating layer 1231 by using such as the deposition, exposure or development process, wherein the second portion 1242 of the absorption layer 124 covers a portion of the drain 123d and a portion of the data lines 121.

As indicated in FIG. 15E, a second insulating layer 1232 covering the channel layer 123p and the absorption layer 124 (the covered structure is denoted by dotted lines) is formed by using such as the deposition or development process.

As indicated in FIG. 15E, a second aperture 1232a exposing the second portion 1242 of the absorption layer 124 is formed on the second insulating layer 1232 by using such as the patterning technology.

The pixel electrode 125 of FIGS. 7A and 7B is formed on the second insulating layer 1232 by using such as the deposition, exposure or development process, wherein the region of the pixel electrode 125 corresponds to the first portion 1241 of the absorption layer 124, and is electrically connected to the second portion 1242 of the absorption layer 124 via the corresponding second aperture 1232a.

The manufacturing method of the TFT array panel of FIGS. 8A and 9 is similar to that of FIG. 7A, and the similarities are not repeated here.

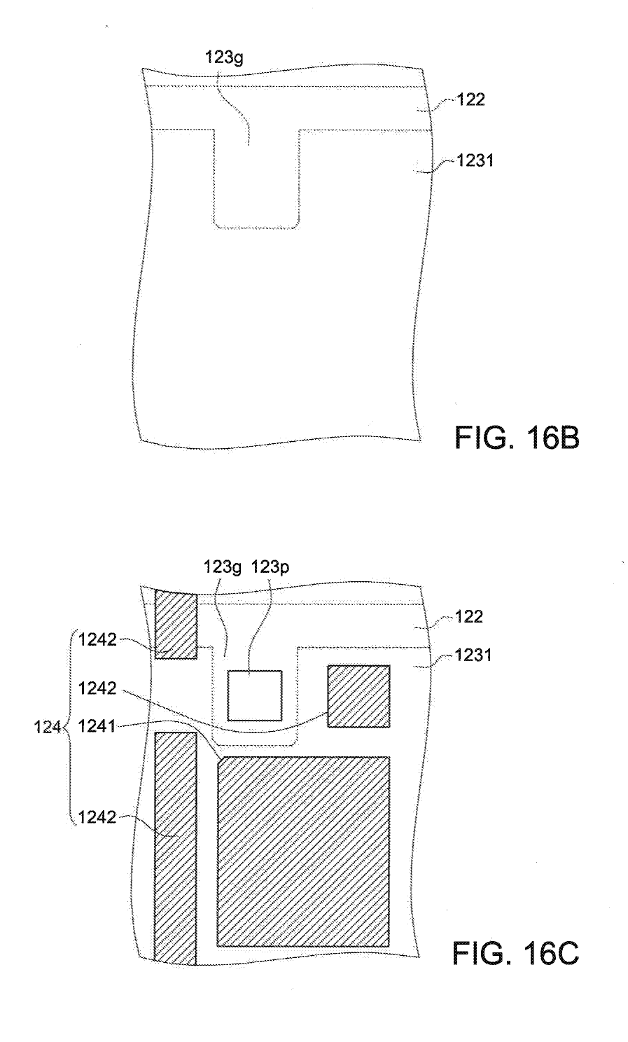

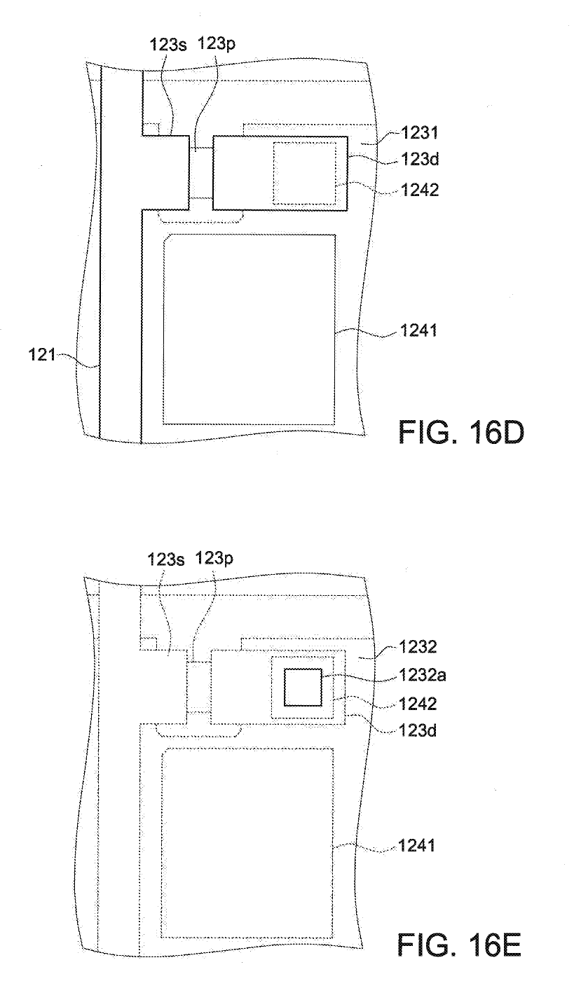

Referring to FIGS. 16A˜16E, processes of a manufacturing method of a TFT array panel of FIG. 10A are shown.

As indicated in FIG. 16A, a substrate 110 having an upper surface 110u is provided.

As indicated in FIG. 16A, a gate 123g and several scan lines 122 are formed on the upper surface 110u of the substrate 110 by using such as the deposition, exposure or development process.

As indicated in FIG. 16B, a first insulating layer 1231 covering the gate 123g and scan lines 122 (the covered structure is denoted by dotted lines) is formed by using such as the deposition or development process.

As indicated in FIG. 16C, a channel layer 123p and an absorption layer 124 are concurrently formed on the first insulating layer 1231 by using such as the deposition, exposure or development process, wherein the region of the channel layer 123p corresponds to the gate 123g, and the absorption layer 124 comprises a first portion 1241 and a second portion 1242.

As indicated in FIG. 16D, several data lines 121, a source 123s and a drain 123d are formed on the first insulating layer 1231 by using such as the deposition, exposure or development process, wherein the data lines 121, the source 123s and the drain 123d cover at least one portion of the second portion 1242 of the absorption layer 124, but the data lines 121, the source 123s and the drain 123d completely cover the second portion 1242 of the absorption layer 124 in the present embodiment. The source 123s and the drain 123d are connected to the channel layer 123p.

As indicated in FIG. 16E, a second insulating layer 1232 covering the channel layer 123p, the absorption layer 124 (is illustrated in FIG. 16C), the source 123s and the drain 123d (the covered structure is denoted by dotted lines) is formed by using such as the deposition or development process.

Then, a second aperture 1232a exposing the second portion 1242 of the absorption layer 124 is formed on the second insulating layer 1232 by using such as the patterning technology.

Then, the pixel electrodes 125 of FIG. 10A is formed on the second insulating layer 1232 by using such as the deposition, exposure or development process, wherein the region of the pixel electrode 125 corresponds to the first portion 1241 of the absorption layer 124, and is electrically connected to the second portion 1242 of the absorption layer 124 via the corresponding second aperture 1232a.

The manufacturing method of the TFT array panel of FIGS. 11A and 12 is similar to that of FIG. 10A, and the similarities are not repeated here.

According to the above embodiments of the disclosure, a portion of the absorption layer 124 can be electrically connected to the active elements 123, and another portion can be electrically isolated from the active elements 123. The entire absorption layer 124 and the active element 123 can be electrically connected to or isolated from each other. If the absorption layer 124 and the active element 123 are electrically connected to each other, the absorption layer 124 is covered by a light blocking structure (formed by the source, the drain, the data lines and/or the scan lines) to avoid the absorption layer 124 being radiated by the light. If the absorption layer 124 and the active elements 123 are electrically isolated from each other, the absorption layer 124 may or may not be radiated by the light. At least one portion of the absorption layer overlaps at least one portion of at least one of several data lines, at least one portion of at least one of several scan lines, at least one portion of at least one of several drains and/or at least one portion of at least one of several sources. The absorption layer may be located above or underneath these structures according to the varieties of the active elements used in practical application, and the embodiments of the disclosure do not impose further restrictions. The varieties of the active elements of the embodiments of the disclosure are not limited to the four types exemplified above, and any types of active elements would do. Furthermore, the TFT array panel 100 can be used in any types of display panels, such as liquid crystal display panel, 3D display panel, or active-matrix organic light-emitting diode display panel.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A thin film transistor (TFT) array display panel, comprising:
a substrate having an upper surface;
a pixel array formed on the upper surface of the substrate and comprising:
a plurality of data lines;
a plurality of scan lines, wherein the scan lines and the data lines define a plurality of pixel areas;
a plurality of active elements, each being formed in the corresponding pixel areas and comprising a channel layer; and
an absorption layer, wherein the absorption layer and the channel layer are made of the same material and are formed on the same layer structure.

2. The TFT array panel according to claim 1, wherein each active element comprises a source and a drain, and at least one portion of the absorption layer overlaps at least one of the sources, the drains, the data lines and the scan lines.

3. The TFT array panel according to claim 1, wherein each active element further comprises a source and a drain, the channel layer is connected to the source and the drain, the absorption layer comprises a first portion and a second portion, wherein the first portion of the absorption layer, the source, the drain and the channel layer are formed on the upper surface of the substrate, and the second portion of the absorption layer covers at least one of the data lines, the source and the drain.

4. The TFT array panel according to claim 3, wherein the pixel array further comprises a first insulating layer covering the source, the drain, the channel layer and the absorption layer and has a first aperture exposing the second portion of the absorption layer; and each active element further comprises:
a gate formed on the first insulating layer, wherein the region of the gate corresponds to the channel layer;
an electrical connection portion contacting the second portion of the absorption layer via the first aperture; and
a second insulating layer covering the gate and the electrical connection portion and having a second aperture exposing the electrical connection portion;
the pixel array further comprises:
a plurality of pixel electrodes formed on the second insulating layer, wherein each pixel electrode is electrically connected to the corresponding electrical connection portion via the corresponding second aperture of the second insulating layer.

5. The TFT array panel according to claim 1, wherein the entire absorption layer and the channel layer are formed on the upper surface of the substrate.

6. The TFT array panel according to claim 1, wherein each active element comprises a gate, a source, a drain and an insulating layer, the gate is formed on the upper surface of the substrate, the insulating layer covers the gate, the source, the drain and the channel layer, the absorption layer is formed on the insulating layer, and a portion of the absorption layer covers the source and the drain.

7. The TFT array panel according to claim 1, wherein the pixel array further comprises a plurality of pixel electrodes each contacting the absorption layer.

8. The TFT array panel according to claim 1, wherein each active element comprises a gate, a source and a drain, the gate covers the upper surface of the substrate, the pixel array further comprises an insulating layer covering the gate, the source, the drain and the channel layer, the absorption layer is formed on the insulating layer, and the source and the drain covers a portion of the absorption layer.

9. The TFT array panel according to claim 1, wherein the pixel array further comprises a plurality of pixel electrodes, the absorption layer comprises a first portion and a second portion separated from the first portion, the region of the first portion corresponds to the pixel electrode, and the second portion is electrically connected to a drain of the active element.

10. The TFT array panel according to claim 1, wherein each pixel array further comprises a plurality of pixel electrodes, the absorption layer comprises a first portion and a second portion connected to the first portion, the region of the first portion corresponds to the pixel electrode, and the second portion is electrically connected to a drain of the active element.

11. The TFT array panel according to claim 1, wherein the absorption layer is formed by doping indium, aluminum, gallium, tin, hafnium or a combination thereof to a zinc oxide film.

12. A manufacturing method of TFT display panel, comprising:
providing a substrate having an upper surface; and
forming a pixel array on the upper surface of the substrate, wherein the method further comprises:
forming a plurality of data lines on the substrate;
forming a plurality of scan lines on the substrate, wherein the scan lines and the data lines define a plurality of pixel areas; and
concurrently forming a channel layer and an absorption layer of an active element, wherein the absorption layer and the channel layer are made of the same material and formed on the same layer structure.

13. The manufacturing method according to claim 12, wherein the step of forming the data lines on the substrate comprises:
forming a drain and a source of the active element on the upper surface of the substrate;
in the step of concurrently forming the channel layer and the absorption layer of the active element, the channel layer and a first portion of the absorption layer are formed on the upper surface of the substrate, and a second portion of the absorption layer covers at least one of the data lines, the source and the drain.

14. The manufacturing method according to claim 13, wherein the step of forming the pixel array on the upper surface of the substrate comprises:
forming a first insulating layer covering the source, the drain, the channel layer and the absorption layer;
forming a first aperture on the first insulating layer, wherein the first aperture exposes the second portion of the absorption layer;
forming a gate on the first insulating layer, wherein the region of the gate corresponds to the channel layer;
forming an electrical connection portion on the first insulating layer, wherein the electrical connection portion contacts the second portion of the absorption layer via the first aperture;
forming a second insulating layer covering the gate and the electrical connection portion;
forming a second aperture on the second insulating layer, wherein the second aperture exposes the electrical connection portion; and
forming a plurality of transparent pixel electrodes on the second insulating layer, wherein each pixel electrode is electrically connected to the second portion of the absorption layer via the corresponding second aperture.

15. The manufacturing method according to claim 12, wherein in the step of concurrently forming the channel layer and the absorption layer of the active element, the entire absorption layer and the channel layer cover the upper surface of the substrate.

16. The manufacturing method according to claim 12, wherein the step of forming the pixel array on the upper surface of the substrate comprises:
forming a gate of the active element on the upper surface of the substrate;
forming an insulating layer covering the gate;
the step of forming the data lines on the substrate comprises:
forming a drain and a source of the active element on the insulating layer;
in the step of concurrently forming the channel layer and the absorption layer of the active element, the channel layer and the absorption layer cover the insulating layer, and a portion of the absorption layer covers the source and the drain.

17. The manufacturing method according to claim 12, wherein the step of forming the pixel array on the upper surface of the substrate comprises:
forming a plurality of pixel electrodes each contacting the absorption layer.

18. The manufacturing method according to claim 12, wherein the step of forming the pixel array on the upper surface of the substrate comprises:
forming a gate of the active element on the upper surface of the substrate;
forming an insulating layer covering the gate;
in the step of concurrently forming the channel layer and the absorption layer of the active element, the channel layer and the absorption layer are formed on the insulating layer;
the step of forming the data lines on the substrate comprises:
forming a drain and a source of the active element covering the insulating layer, wherein the source and the drain cover a portion of the absorption layer.

19. The manufacturing method according to claim 12, wherein in the step of concurrently forming the channel layer and the absorption layer of the active element, the absorption layer comprises a first portion and a second portion separated from the first portion;
the step of forming the pixel array on the upper surface of the substrate comprises:
forming a plurality of pixel electrodes, wherein the region of the pixel electrode corresponds to the first portion;
wherein, the second portion is electrically connected to a drain of the active element.

20. The manufacturing method according to claim 12, wherein in the step of concurrently forming the channel layer and the absorption layer of the active element, the absorption layer comprises a first portion and a second portion connected to the first portion;
the step of forming the pixel array on the upper surface of the substrate comprises:
forming a plurality of pixel electrodes, wherein the region of the pixel electrode corresponds to the first portion;
wherein, the second portion is electrically connected to a drain of the active element.

21. The manufacturing method according to claim 12, wherein the absorption layer is formed by doping indium, aluminum, gallium, tin, hafnium or a combination thereof to a zinc oxide film.
